(19) United States
(12) Patent Application Publication
(10) Pub. No.: US 2026/0075908 A1
(43) Pub. Date: Mar. 12, 2026

(54) SEMICONDUCTOR STRUCTURE INCLUDING FIELD EFFECT TRANSISTOR WITH SCALED GATE LENGTH AND METHOD

(71) Applicant: GlobalFoundries U.S. Inc., Malta, NY (US)

(72) Inventors: Anton V. Tokranov, Halfmoon, NY (US); Saloni Chaurasia, Leander, TX (US); Hong Yu, Clifton Park, NY (US); Jagar Singh, Clifton Park, NY (US)

(21) Appl. No.: 19/390,900

(22) Filed: Nov. 17, 2025

Related U.S. Application Data
(62) Division of application No. 17/816,799, filed on Aug. 2, 2022.

(51) Int. Cl. H10D 64/01; H10D 30/01; H10D 30/62; H10D 84/01; H10D 84/03

(52) U.S. Cl. CPC H10D 64/017; H10D 30/024; H10D 30/6211; H10D 64/021; H10D 84/0147; H10D 84/0158; H10D 84/038

(57) ABSTRACT

A disclosed structure includes a FET with a gate structure (e.g., a RMG structure) having a scaled effective gate length proximal to a channel region and a large conductor surface distal to the channel region. The gate structure includes a first portion within a lower region of a gate opening proximal to the channel region and a second portion within a wider upper region. In this case, the gate structure can include a conformal gate dielectric layer that lines the gate opening and a gate conductor layer thereon. Alternatively, the gate structure includes a first portion including a short gate dielectric layer proximal to the channel region and a second portion (including a conformal gate dielectric layer and gate conductor layer) on the lower portion in a gate opening. Optionally, the structure also includes an additional FET without the scaled effective gate length. Also disclosed are associated methods.

### BACKGROUND

### Field of the Invention

The present invention relates to semiconductor devices and, more particularly, to embodiments of a semiconductor structure including a field effect transistor (FET) and to embodiments of a method of forming the semiconductor structure.

### Description of Related Art

Radio frequency (RF) integrated circuit (RFIC) chips could benefit from the inclusion of at least some FETs (e.g., at least some fin-type FETs (FINFETs)) with reduced effective gate lengths. However, conventional lithographic patterning techniques for defining gate critical dimension (CD) are limited. Furthermore, scaling the gate CD can result in a gate contact landing area that is too small. Additionally, in replacement metal gate (RMG) processing scaling the gate CD can result in a gate opening that is too small to fill with a RMG without the formation of voids or defects.

### SUMMARY

Disclosed herein are embodiments of a structure. The structure can include a gate structure. The gate structure can include a gate dielectric layer and a gate conductor layer. Additionally, the gate structure can have a first portion and a second portion. The first portion can be on a semiconductor body. The second portion can be on the first portion and can have an edge region that extends laterally beyond the first portion. The structure can further include a gate sidewall spacer. The gate sidewall spacer can have a first section, which is positioned laterally adjacent to the first portion of the gate structure between the edge region of the second portion of the gate structure and the semiconductor body, and a second section, which is positioned laterally adjacent to the first section and to the second portion of the gate structure. The gate sidewall spacer can be physically separated from the gate conductor layer by the gate dielectric layer.

Some embodiments of a structure disclosed herein can more specifically include a substrate and a field effect transistor (FET), such as a fin-type FET (FINFET), on the substrate. The FINFET can include a semiconductor fin. The FINFET can further include a gate structure. The gate structure can include a gate dielectric layer and a gate conductor layer. The gate structure can further have a first portion and a second portion. The first portion can be on the top surface and opposing sides of the semiconductor fin and the second portion can be on the first portion and can have an edge region that extends laterally beyond the first portion. The FINFET can further include a gate sidewall spacer with a first section and a second section. The first section of the gate sidewall spacer can be positioned laterally adjacent to the first portion of the gate structure between the edge region of the second portion of the gate structure and the semiconductor fin. The second section of the gate sidewall spacer can be positioned laterally adjacent to the first section and to the second portion of the gate structure. The gate sidewall spacer can be physically separated from the gate conductor layer by the gate dielectric layer. Optionally, the embodiment of the structure can further include an additional FINFET on the substrate and the additional FINFET can include an additional gate structure with a longer effective gate length than the gate structure.

Also disclosed herein are method embodiments for forming the disclosed structure embodiments. The method embodiments can include providing a substrate and forming, on the substrate, a structure. The structure can include a gate structure. The gate structure can include a gate dielectric layer and a gate conductor layer. Additionally, the gate structure can have a first portion and a second portion. The first portion can be on a semiconductor body. The second portion can be on the first portion and can have an edge region that extends laterally beyond the first portion. The structure can further include a gate sidewall spacer. The gate sidewall spacer can have a first section, which is positioned laterally adjacent to the first portion of the gate structure between the edge region of the second portion of the gate structure and the semiconductor body, and a second section, which is positioned laterally adjacent to the first section and to the second portion of the gate structure. The gate sidewall spacer can be physically separated from the gate conductor layer by the gate dielectric layer.

### BRIEF DESCRIPTION OF THE SEVERAL VIEWS OF THE DRAWINGS

The present invention will be better understood from the following detailed description with reference to the drawings, which are not necessarily drawn to scale and in which:

FIGS. 1A-1D are different cross-section diagrams illustrating a disclosed embodiment of a semiconductor structure including a FET (e.g., a FINFET) with a scaled effective gate length;

FIGS. 2A-2D are different cross-section diagrams illustrating another disclosed embodiment of a semiconductor structure including a FET (e.g., a FINFET) with a scaled effective gate length;

FIG. 3 is a flow diagram illustrating method embodiments for forming the disclosed semiconductor structure embodiments (e.g., of FIGS. 1A-1D and FIGS. 2A-2D);

FIGS. 4A-4C are different cross-section diagrams illustrating a partially completed semiconductor structure formed according to the flow diagram of FIG. 3;

FIGS. 5A-5C are different cross-section diagrams illustrating a partially completed semiconductor structure formed according to the flow diagram of FIG. 3;

FIGS. 6A-6C are different cross-section diagrams illustrating a partially completed semiconductor structure formed according to the flow diagram of FIG. 3;

FIGS. 7A-7C are different cross-section diagrams illustrating a partially completed semiconductor structure formed according to the flow diagram of FIG. 3;

FIGS. 8A-8C are different cross-section diagrams illustrating a partially completed semiconductor structure formed according to the flow diagram of FIG. 3;

FIGS. 9A-9D are different cross-section diagrams illustrating a partially completed semiconductor structure formed according to the flow diagram of FIG. 3;

FIGS. 10A-10D are different cross-section diagrams illustrating a partially completed semiconductor structure formed according to the flow diagram of FIG. 3;

FIGS. 11A-11C are different cross-section diagrams illustrating a partially completed semiconductor structure formed according to the flow diagram of FIG. 3;

FIGS. 12A-12C are different cross-section diagrams illustrating a partially completed semiconductor structure formed according to the flow diagram of FIG. 3;

FIGS. 13A-13C are different cross-section diagrams illustrating a partially completed semiconductor structure formed according to the flow diagram of FIG. 3;

FIGS. 14A-14C are different cross-section diagrams illustrating a partially completed semiconductor structure formed according to the flow diagram of FIG. 3;

FIGS. 15A-15C are different cross-section diagrams illustrating a partially completed semiconductor structure formed according to the flow diagram of FIG. 3; and

FIGS. 16A-16C are different cross-section diagrams illustrating a partially completed semiconductor structure formed according to the flow diagram of FIG. 3.

### DETAILED DESCRIPTION

As mentioned above, radio frequency (RF) integrated circuit (RFIC) chips could benefit from the inclusion of at least some FETs (e.g., at least some fin-type FETs (FINFETs) with reduced effective gate lengths. However, conventional lithographic patterning techniques for defining gate critical dimension (CD) are limited. Furthermore, scaling the gate CD can result in a gate contact landing area that is too small. Additionally, replacement metal gate (RMG) processing scaling the gate CD can result in a gate opening that is too small to fill with a RMG without the formation of voids or defects.

In view of the foregoing, disclosed herein are embodiments of a semiconductor structure including a substrate and, on the substrate, a FET (e.g., a FINFET) having a scaled effective gate length. Specifically, the FET can include a gate structure (e.g., an RMG structure) with a relatively short gate length proximal to a channel region, but a relatively large gate length distal to the channel region (e.g., for a relatively large surface area for contact landing). In some embodiments, the gate structure can include a first portion, which is within a narrow region of a gate opening proximal to the channel region, and a second portion, which is within a wider region of the same gate opening on the narrow region and distal to the channel region. In this case, the gate structure can include a conformal gate dielectric layer that lines the gate opening and a gate conductor layer thereon. In other embodiments, the gate structure can include a first portion, which includes a relatively thick and short gate dielectric layer proximal to the channel region, and a second portion, which is on the first portion distal to the channel region, and which fills a gate opening. In this case, the second portion can include a conformal gate dielectric layer that lines the gate opening and a gate conductor layer thereon. In some embodiments, the semiconductor structure can further include, on the same substrate, an additional FET with a corresponding additional gate structure that does not have a scaled effective gate length. In each of the embodiments, gate sidewall spacers are on opposing sides of the gate structure (e.g., to isolate the gate structure from adjacent source/drain regions, respectively) and each gate structure has a first section and a second section with the first section positioned laterally adjacent to the first portion of the gate structure and the second section positioned laterally adjacent to the first section and to the second portion of the gate structure. The FET (e.g., the FINFET) as described above can exhibit improved performance because the disclosed gate structure configuration with the reduced effective gate length has the added benefit of lowering overlap capacitance and, thereby limiting performance degradation due to overlap capacitance. Also disclosed herein are method embodiments of forming the semiconductor structure including forming the FET, as described above, with a scaled effective gate length and, optionally, concurrently forming the additional FET without the scaled effective gate length.

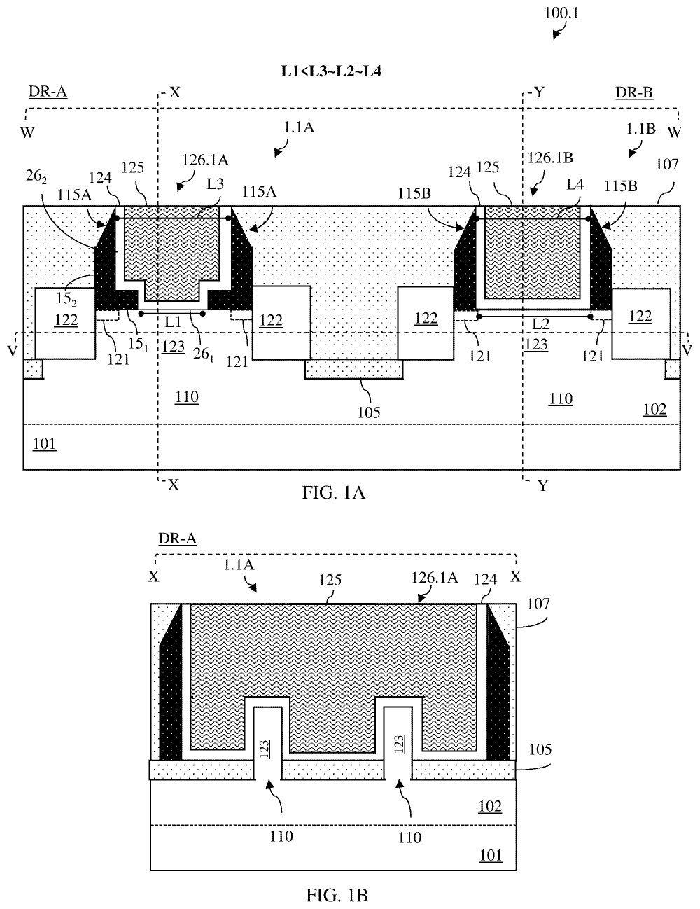

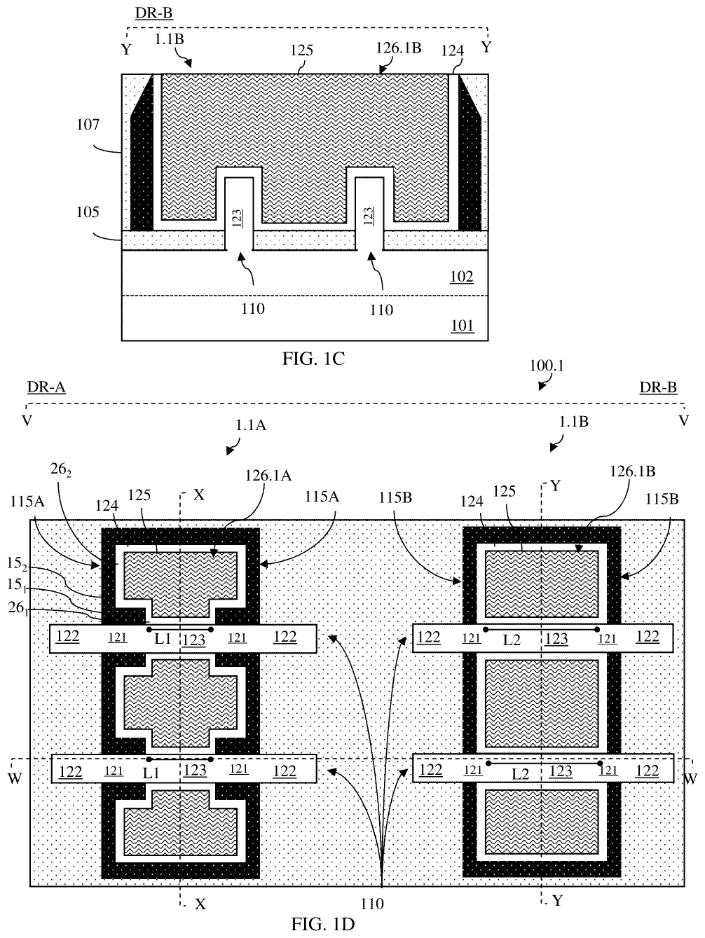

FIG. 1A is a vertical cross-section WW diagram of an embodiment of a semiconductor structure 100.1 including a FET 1.1A in a device region A (DR-A) and having a scaled effective gate length and, optionally, including an additional FET 1.1B in an additional device region B (DR-B) without a scaled effective gate length. As illustrated, the vertical cross-section WW is along the length of the FETs. FIG. 1B is a vertical cross-section XX diagram perpendicular to WW and traversing the center of the FET 1.1A and FIG. 1C is a vertical cross-section YY diagram perpendicular to WW and traversing the center of the FET 1.1B. FIG. 1D is a horizontal cross-section VV of the semiconductor structure 100.1.

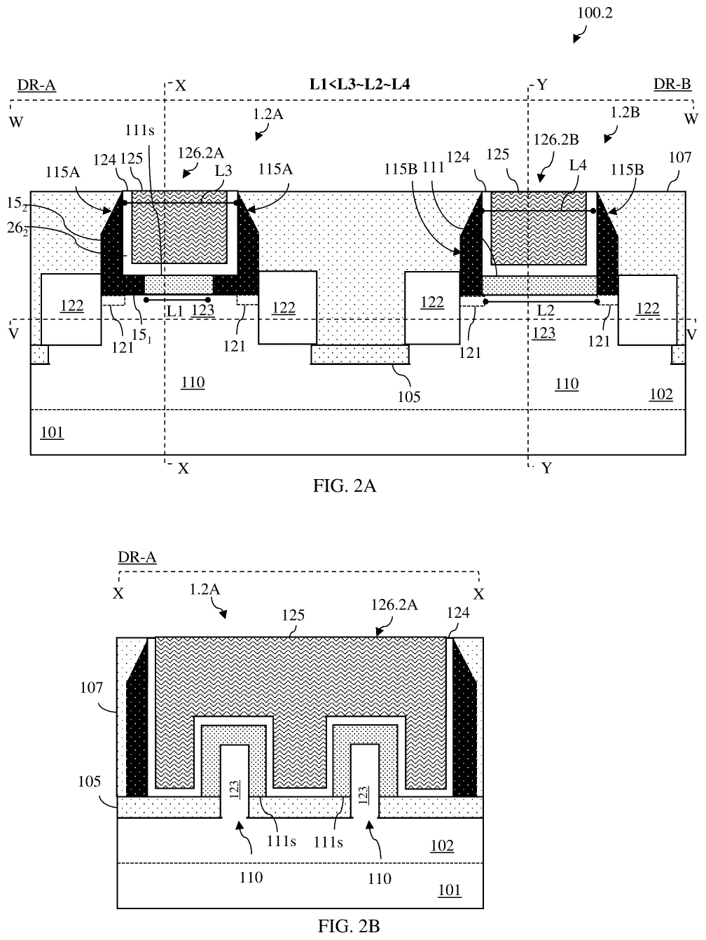

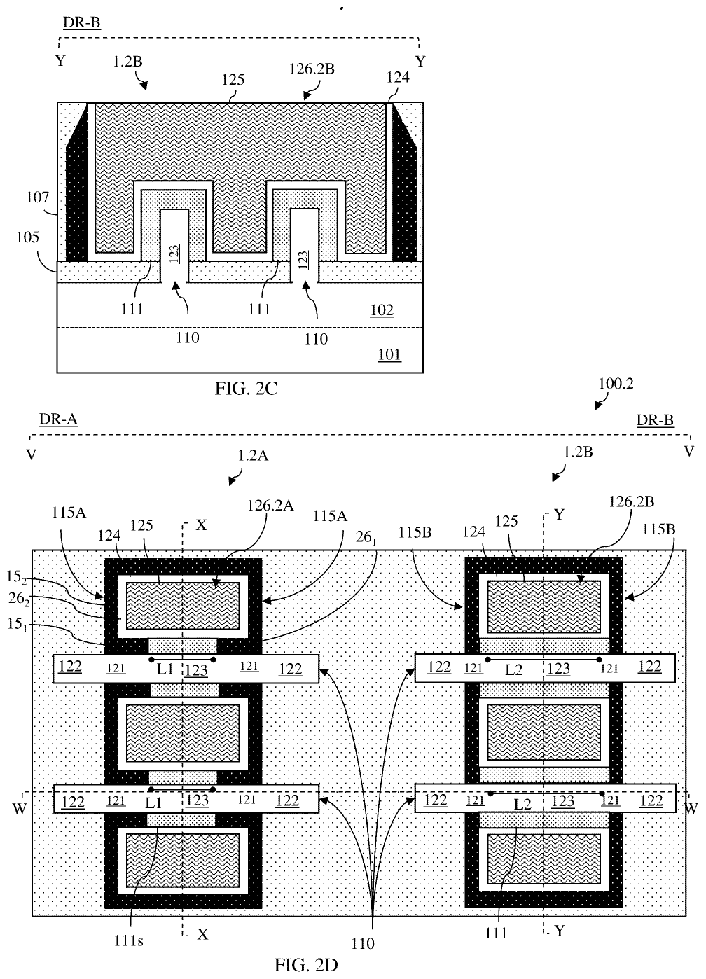

FIG. 2A is a vertical cross-section WW diagram of an embodiment of a semiconductor structure 100.2 including a FET 1.2A in DR-A and having a scaled effective gate length and, optionally, including an additional FET 1.2B in DR-B without a scaled effective gate length. As illustrated, the vertical cross-section WW is along the length of the FETs. FIG. 2B is a vertical cross-section XX diagram perpendicular to WW and traversing the center of the FET 1.2A and FIG. 2C is a vertical cross-section YY diagram perpendicular to WW and traversing the center of the FET 1.2B. FIG. 2D is a horizontal cross-section VV of the semiconductor structure 100.2.

Referring to FIGS. 1A-1D and 2A-2D, the semiconductor structure 100.1, 100.2 can include a substrate 101 and one or more FETs, as described in greater detail below on the substrate 101. As illustrated, the semiconductor structure 100.1, 100.2 could be a bulk semiconductor structure, where the substrate 101 is a bulk semiconductor substrate, such as a bulk monocrystalline silicon substrate or a bulk substrate of some other monocrystalline semiconductor material, and where the FET(s) are formed using an upper portion of the substrate 101. In this case, one or more well regions 102 can, as necessary, isolate the FET(s) or other devices in the upper portion of the substrate 101 from the lower portion of the substrate 101. However, it should be understood that the figures are not intended to be limiting. For example, although not illustrated, the semiconductor structure 100.1, 100.2 could, alternatively, be semiconductor-on-insulator structure (e.g., a silicon-on-insulator (SOI) structure) including a semiconductor substrate (e.g., a monocrystalline silicon substrate), an insulator layer (e.g., a buried oxide (BOX) layer) on the semiconductor substrate, and a semiconductor layer (e.g., a monocrystalline silicon layer) on the insulator layer. In this case the FET(s) could be formed using the semiconductor layer.

As mentioned above, the semiconductor structure 100.1, 100.2 can further include one or more FETs and, more particularly, at least one FET 1.1A, 1.2A with a scaled effective gate length. Optionally, as illustrated, the semiconductor structure 100.1, 100.2 can further include at least one additional FET 1.2A, 1.2B without a scaled effective gate length.

In any case, the FET 1.1A, 1.2A (and, if included, the additional FET 1.1B, 1.2B) can include a semiconductor body 110. The FET 1.1A, 1.2A (and, if included, the additional FET 1.1B, 1.2B) can further include a channel region 123 within the semiconductor body 110. The FET 1.1A, 1.2A (and, if included, the additional FET 1.1B, 1.2B) can further include source/drain regions 122 (e.g., doped semiconductor regions of the semiconductor body 110, doped epitaxial semiconductor regions filling trenches within the semiconductor body 110, or any other suitable type of source/rain regions). The FET 1.1A, 1.2A (and, if included, the additional FET 1.1B, 1.2B) can further include a channel region 123 within the semiconductor body 110 positioned laterally between the source/drain regions 122 and a gate structure (as discussed in greater detail below) on the semiconductor body 110 adjacent to the channel region 123. The channel region 123 can have a first type conductivity at a relatively low conductivity level. Alternatively, the channel region 123 can be an intrinsic region. The source/drain regions 122 can have a second type conductivity different from the first type conductivity at a relatively high conductivity level. Optionally, each FET can also include a source/drain extension region 121 on one or both sides of the channel region 123 extending to the adjacent source/drain region 122. The source/drain extension region(s) 121 can have the second type conductivity at a relatively low conductivity level.

The FET 1.1A, 1.2A can be an N-type FET (NFET) or a P-type FET (PFET). If included in the semiconductor structure 100.1, 100.2, the FET 1.1B, 1.2B can have the same type conductivity as the FET 1.1A, 1.2A or can have a different type conductivity. In other words, FETs 1.1A, 1.2A and 1.1B, 1.2B could both be NFETs, could both be PFETs, or can be a combination of N and PFETs. That is, the FET 1.1A, 1.2A could be an NFET and the FET 1.2A, 1.2B could be a PFET or vice versa. Those skilled in the art will recognize that, in any given FET within the structure, the first type conductivity and the second type conductivity mentioned above with regard to the channel and source/drain regions will vary depending upon whether the FET is an NFET or a PFET. Specifically, for an NFET, the first type conductivity of the channel region is P-type conductivity and the second type conductivity of the source/drain regions (and if applicable the source/drain extension region(s)) is N-type conductivity; whereas, for a PFET, the first type conductivity of the channel region is N-type conductivity and the second type conductivity of the source/drain regions (and if applicable the source/drain extension region(s)) is P-type conductivity. See the detailed discussion below regarding the material-specific dopants that can be implanted, diffused, or otherwise integrated into a semiconductor material in order to achieve either P-type conductivity or N-type conductivity.

The FET 1.1A, 1.2A can have a gate structure 126.1A, 126.2A with gate sidewall spacers 115A and a scaled effective gate length (L1). The optional additional FET 1.1B, 1.2B can have an additional gate structure 126.1B, 126.2B with gate sidewall spacers 115B but without a scaled effective gate length (i.e., with an effective gate length (L2) that is greater than L1).

It should be understood that the FET(s) in the disclosed semiconductor structure can be any type of FET, for example, planar FET(s), fin-type FET(s) (FINFET(s)), etc., with any type of gate structure. However, for purposes of illustration and, particularly, to illustrate the unique physical configuration of the gate structure with the scaled effective gate length (L1), the FET(s) of the semiconductor structure 100.1 of FIGS. 1A-1D and of the semiconductor structure 100.2 of FIGS. 2A-2D are described below and illustrated in the figures as being FINFET(s) with replacement metal gate(s) (RMGs).

Each FINFET can include one or more semiconductor bodies 110 specifically in the form of semiconductor fins. For purposes of this disclosure, a “semiconductor fin” refers to a relatively thin, elongated, semiconductor body. Ideally, a semiconductor fin will have a three-dimensional rectangular shape with a uniform width from the bottom of the semiconductor fin proximal to the substrate to the top of the semiconductor fin distal from the substrate. However, those skilled in the art will recognize that semiconductor fins are typically formed using a selective anisotropic etch process and, as a result of this process, the sidewalls of the semiconductor fins may not be exactly vertical (i.e., perpendicular to the bottom surface of the substrate) and the fin width may be somewhat non-uniform (e.g., wider proximal to the substrate). Optionally, each FINFET can include multiple parallel semiconductor fins. As illustrated, in the VV, XX, YY cross-sections, each FINFET is illustrated as having two semiconductor fins 110. However, it should be understood that each FINFET could include any number of one or more semiconductor fins. Furthermore, the number of semiconductor fins in the FINFETs could be the same (as illustrated) or different. In a bulk semiconductor structure, as illustrated, the semiconductor fin(s) 110 can be patterned and etched in the upper portion of the substrate 101 such that they extend essentially vertically from the substrate. In this case, an insulator layer 105 (e.g., a silicon dioxide layer) can be on the substrate 101 laterally surrounding the lower portion of each semiconductor fin and extending between the fins to form an isolation region. It should be noted that each semiconductor fin can be a discretely patterned semiconductor fin, as illustrated. However, again, the figures are not intended to be limiting. Alternatively, during processing relatively long semiconductor fins could be formed and shallow trench isolation regions (STI) regions (not shown) can segment the long semiconductor fins into multiple shorter semiconductor fins.

The RMG structure of the FINFETs can include at least a gate dielectric layer 124 and a gate conductor layer 125 on the gate dielectric layer 124. The gate dielectric layer 124 can include a high-K gate dielectric layer; and a gate conductor layer 125 can include one or more work function (WF) metal or metal alloy layers on the high-K gate dielectric layer and, optionally, a conductive fill material on the WF metal or metal alloy layer(s). Those skilled in the art will recognize that a high-K gate dielectric layer refers to a layer of dielectric material with a dielectric constant that is greater than the dielectric constant of silicon dioxide (i.e., greater than 3.9). Illustrative high-K dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). The WF metal or metal alloy layer(s) can be selected to achieve the optimal WF depending upon the conductivity type of the FET (i.e., optimal NFET WF for an NFET or optimal PFET WF for a PFET). Those skilled in the art will further recognize that the optimal WF for a gate conductor of an NFET will be, for example, between 3.9 eV and about 4.2 eV. Metals (and metal alloys) that have a work function within this range include, but are not limited to, hafnium, zirconium, titanium, tantalum, aluminum, and alloys thereof, such as, hafnium carbide, zirconium carbide, titanium carbide, tantalum carbide, and aluminum carbide. Those skilled in the art will further recognize that the optimal WF for a gate conductor of PFET will be, for example, between about 4.9 eV and about 5.2 eV. Metals (and metal alloys) that have a work function within this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). Alternatively, the WF metal or metal alloy layer(s) can be metal or metal alloy materials that are selected due to suitability for use in either NFETs or PFETs. The optional conductive fill material layer can be, for example, doped polysilicon or any suitable metal or metal alloy fill material including, but not limited to, tungsten, a tungsten alloy (e.g., tungsten silicide or titanium tungsten), cobalt, or aluminum.

In any case, those skilled in the art will recognize that, for a single-fin FINFET, the gate structure will be adjacent to the top surface and opposing sides of the single semiconductor fin. For a multi-fin FINFET, the gate structure will traverse all semiconductor fins and will be adjacent to the top and opposing sides of each semiconductor fin. Additionally, isolation of the FINFETs from the substrate 101 below and from each other is achieved through the insulator layer 105, which is below the gate structures, and further through one or more additional dielectric layers 107 (e.g., including one or more layers of dielectric material, interlayer dielectric (ILD) material) laterally surrounding the FINFETs. The ILD material can include, for example, one or more layers of silicon dioxide, silicon nitride, a doped silicon glass (e.g., phosphosilicate glass (PSG) or borophosphosilicate glass (BPSG)), or any other suitable ILD material.

In the FET 1.1A, 1.2A, the gate structure 126.1A, 126.2A can include a first portion 26₁ and a second portion 26₂. The first portion 26₁ can be proximal to and, particularly, on and immediately adjacent to the top surface and opposing sides (see FIGS. 1A-1B and 2A-2B) of the semiconductor fin(s) 110 at the channel region(s) 123 therein. The second portion 26₂ can be on the first portion 26₁ and can be longer than the first portion 26₁ such that edge regions of the second portion 26₂ extends laterally beyond opposing sidewalls of the first portion 26₁ near the source/drain regions 122. Thus, the length (L1) of the first portion 26₁ establishes the scaled effective gate length of the gate structure 126.1A, 126.2A and the length (L3) of the second portion 26₂ is longer than L1. As a result, the top surface of the gate structure 126.1A, 126.2A is sufficiently large to serve as a contact landing area. Due to the techniques used to achieve the first and second portions with the different lengths (L1 and L3, respectively), gate sidewall spacers 115A on the semiconductor body and positioned laterally adjacent to opposing sidewalls of the gate structure 126.1A, 126.2A (e.g., between the gate structure and the adjacent source/drain regions 122, respectively) also have a unique configuration. Specifically, each gate sidewall spacer 115A can have a first section 15₁ and a second section 15₂. The first section 15₁ can be positioned laterally adjacent to the first portion 26₁ of the gate structure 126.1A, 126.2A between an edge region of the second portion 26ₛ of the gate structure 126.1A, 126.2A and the adjacent semiconductor fin 110. The second section 15₂ can be positioned laterally adjacent to the first section 15₁ and to the second portion 26₂ of the gate structure 126.1A, 126.2A. In each of the embodiments, the gate sidewall spacer 115A is physically separated from the gate conductor layer 125 by the gate dielectric layer 124.

In the optional additional FET 1.1B, 1.2B, instead of including two portions with different lengths, the gate structure 126.1B, 126.2B can have an approximately uniform length. That is, the gate structure 126.1B, 126.2B can have a length (L2) proximal to and, particularly, on and immediately adjacent to the top surface and opposing sides of the semiconductor fin(s) 110 at the channel region 123 therein. Furthermore, the gate structure 126.1B, 126.2B can have a length (L4) distal to the fin (e.g., at the top surface of the gate structure) and L4 can be approximately equal to L2. In this case, opposing sidewalls of the gate structure can be essentially planar and planar gate sidewall spacers 115B positioned laterally adjacent thereto. However, those skilled in the art will recognize that, due to processing variations (e.g., during gate stack patterning), the sidewalls of the gate structure 126.1B, 126.2B may not be perfectly parallel/vertical. Thus, although L2 and L4 are described as being approximately equal, it should be understood that L2 may vary somewhat (e.g., be longer or shorter) as compared to L4. Optionally, L2 and L4 of the gate structure 126.1B, 126.2B may also be approximately equal to the length L3 of the gate structure 126.1A, 126.2A (e.g., L1<L2˜L3˜L4).

In some embodiments, the difference between the effective gate lengths L1 and L2 of the gate structures 126.1A, 126.2A and 126.1B, 126.2B, respectively, could, for example, range from 4-10 nm or more or less. For example, in some embodiments, L2 could be 60 nm and L1 could be in the range of 50-56 nm. In other embodiments, L2 could be lower than 25 nm and L1 could be 1, 2, 3 or more nm less. It should be understood that these examples are not intended to be limiting.

Referring specifically to the gate structure 126.1A of the FINFET 1.1A of the semiconductor structure 100.1 of FIGS. 1A-1D, in this case the gate sidewall spacers 115A and, more specifically, both the first and second sections 15₁-15₂ can define a gate opening within which the RMG is formed. In this case, the gate dielectric layer 124 can line the gate opening and the gate conductor layer 125 can be on the gate dielectric layer 124 within the gate opening such that the gate dielectric layer 124 is in both the first and second portions 26₁-26₂ of the gate structure 126.1A and the gate conductor layer 125 may be in both the first and second portions depending on the thickness of the gate dielectric layer 124 relative to the first section 15₁. In this embodiment, the surfaces of the semiconductor fin 110 at the channel region 123, the first section 15₁ of the gate sidewall spacer 115A, and the second section 15₂ of the gate sidewall spacer 115A are immediately adjacent to the gate dielectric layer 124 and separated from the gate conductor layer 125 by the gate dielectric layer 124. It should be noted that the gate structure 126.1B of the optional FINFET 1.1B can similarly have a gate dielectric layer 124 that lines a gate opening defined by gate sidewalls spacers 115B and a gate conductor layer 125 within the gate opening on the gate dielectric layer 124.

Referring specifically to the gate structure 126.2A of the FINFET 1.2A of the semiconductor structure 100.2 of FIGS. 2A-2D, in this case the first portion 26₁ of the gate structure 126.2A can include an additional gate dielectric layer 111s. This additional gate dielectric layer 111s can, for example, be positioned laterally between and in contact with adjacent first sections 15₁ of the gate sidewall spacers 115A on opposing sides of the gate structure 126.2A. The additional gate dielectric layer 111s can be, for example, an oxide layer or a layer of some other suitable gate dielectric material and can have essentially the same thickness as the adjacent first sections 15₁. Optionally, as illustrated, the additional gate dielectric layer 111s in this embodiment can be thicker than the gate dielectric layer 124. Furthermore, in this case, second sections 15₂ only of the gate sidewall spacers 115A can define a gate opening within which the RMG is formed. The gate dielectric layer 124 can line the gate opening and the gate conductor layer 125 can be on the gate dielectric layer 124 within the gate opening such that the gate dielectric layer 124 and the gate conductor layer 125 are in the second portion 26₂ only of the gate structure 126.2A and such that surfaces of the additional gate dielectric layer 111 is, the first section 15₁ of the gate sidewall spacer 115A, and the second section 15₂ of the gate sidewall spacer 115A are immediately adjacent to the gate dielectric layer 124 and separated from the gate conductor layer 125 by the gate dielectric layer 124. It should be noted that the gate structure 126.2B of the optional FINFET 1.2B can similarly have an additional gate dielectric layer 111 immediately adjacent to the semiconductor fin 110. In this case, a gate dielectric layer 124 can line a gate opening defined by gate sidewalls spacers 115B (but only extending down to the additional gate dielectric layer 111 and not exposing the semiconductor fin 110) and a gate conductor layer 125 within the gate opening on the gate dielectric layer 124.

It should be noted that the gate sidewall spacers (e.g., 115A and 115B) can be made of the same sidewall spacer material. This sidewall spacer material can be, for example, silicon nitride, silicon carbon nitride, silicon boron carbon nitride or any other suitable dielectric gate sidewall spacer material that will remain essentially intact during RMG processing (described in greater detail below with regard to the method embodiments) and that will provide the necessary isolation between the gate structure and the adjacent source/drain regions 122. Furthermore, in the gate sidewall spacers 115A, the first section 15₁ may include only this sidewall spacer material. That is, the sidewall spacer material may completely fill the cavity between the outer edge of the second portion 26₂ and the adjacent semiconductor fin 110. Alternatively, the first section 15₁ may include some sidewall spacer material and an airgap. That is, the sidewall spacer material may, during processing, pinch off prior to completely filling the cavity between the outer edge of the second portion 26₂ and the adjacent semiconductor fin 110, thus, forming an airgap (not shown).

Therefore, the semiconductor structure 100.1, 100.2 described above and illustrated in the figures includes one or more FETs including at least one FET 1.1A, 1.2A (e.g., at least one FINFET) with a scaled effective gate length and, optionally, at least one additional FET 1.2A, 1.2B (e.g., at least one additional FINFET) without a scaled effective gate length. It should further be noted that, although not illustrated, the semiconductor structure 100.1, 100.2 could optionally include multiple FETs (e.g., multiple FINFETs) where two or more of the FETs have different scaled effective gate lengths. In any case, any FET with a scaled effective gate length (e.g., FET 1.1A, 1.2A) could be employed, for example, in radio frequency (RF) device or any other device that could benefit from having a gate length that is less than that achievable by conventional processing techniques, whereas any FET without such a scaled effective gate length (e.g., FET 1.1B, 1.2B) could be incorporated into a logic device or other type of device where such a small effective gate length is not deemed critical.

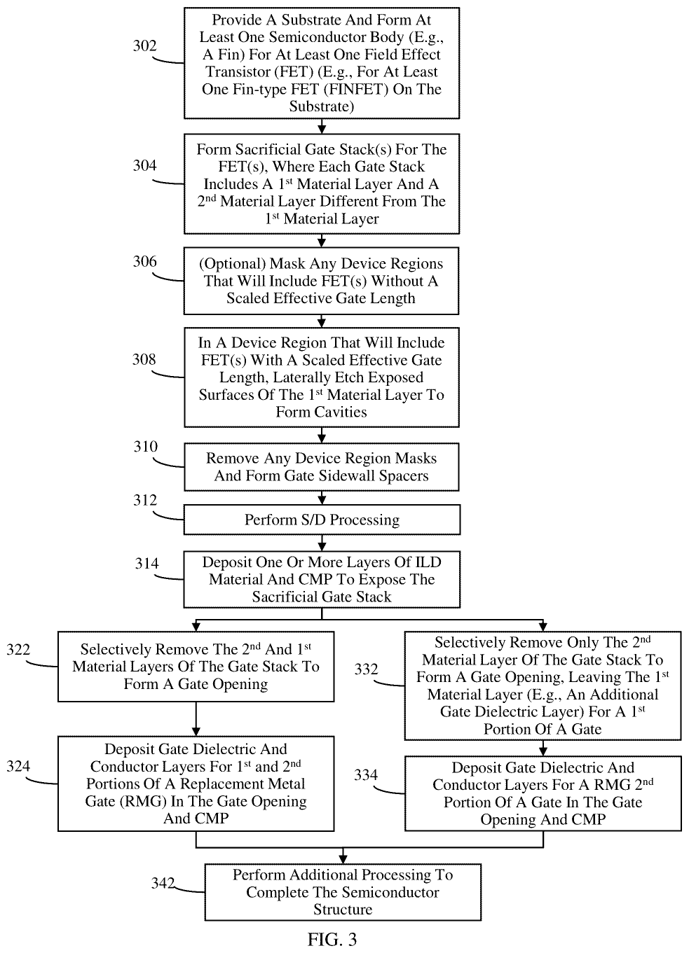

Referring to the flow diagram of FIG. 3, also disclosed herein are method embodiments for forming above-described semiconductor structure embodiments (e.g., the semiconductor structure 100.1 of FIGS. 1A-1D and the semiconductor structure 100.2 of FIGS. 2A-2D).

The method can include providing a substrate (see process 302). For formation of a bulk semiconductor structure (as illustrated), a bulk semiconductor substrate can be provided at process 302. This bulk semiconductor substrate can include, for example, a bulk monocrystalline silicon substrate or a bulk substrate of some other suitable monocrystalline semiconductor material. Alternatively, for a semiconductor-on-insulator structure, a semiconductor-on-insulator (e.g., a silicon-on-insulator (SOI) substrate) can be provided at process 302.

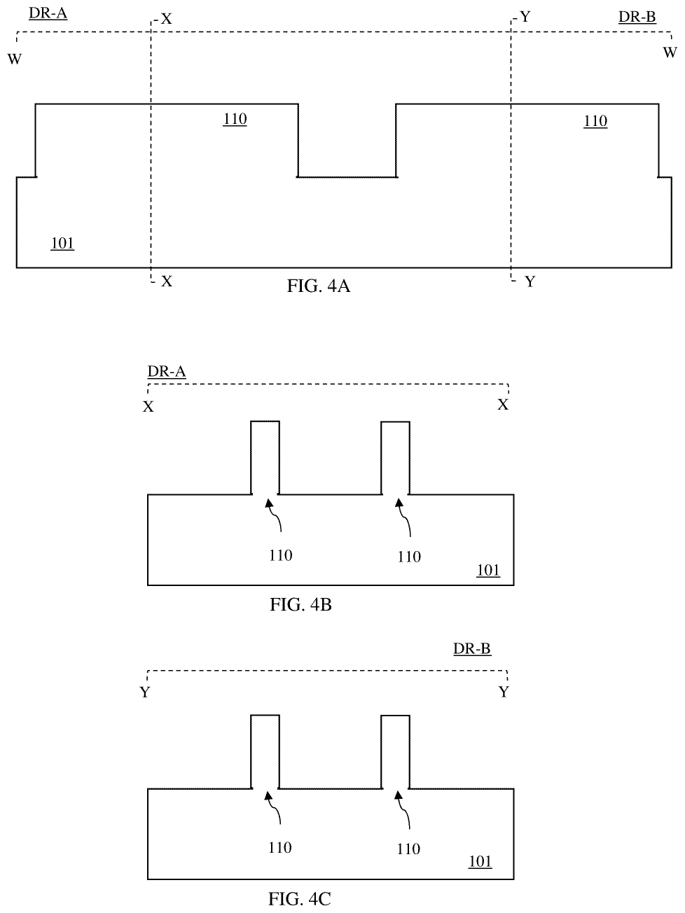

The method can further include forming at least one semiconductor body for at least one field effect transistor (FET) on the substrate (see process 302 and FIGS. 4A-4C). The semiconductor body (or bodies) can be a suitable type of semiconductor body depending upon the type of FET. For example, one or more planar semiconductor bodies can be formed for one or more planar FETs, one or more semiconductor fins can be formed for one or more fin-type FETs (FINFETs), etc. Such semiconductor bodies and the techniques for forming them are well known in the art and, thus, the details thereof have been omitted from this specification in order to allow the reader to focus on the salient aspects of the disclosed embodiments.

For purposes of illustration, FIGS. 4A-4C show a total of four semiconductor fins 110 formed on a bulk semiconductor substrate. The four semiconductor fins include: two semiconductor fins in a device region A (DR-A) to be used in the formation of a FINFET with a scaled effective gate length and two semiconductor fins in a device region B (DR-B) to be used in in concurrent formation of another FINFET that will not have a scaled effective gate length. It should be noted that the figures are not intended to be limiting. That is, formation of a FINFET without the scaled effective gate length is optional. Additionally, any of these FINFETs could be formed using any number of two or more semiconductor fins. The number of semiconductor fins in the FINFETs could be the same (as illustrated) or different. Additionally, for purposes of illustration, formation of discrete semiconductor fins is shown. However, alternatively, relatively long semiconductor fins could be formed with trench isolations regions that divide each long semiconductor fin into multiple shorter semiconductor fins.

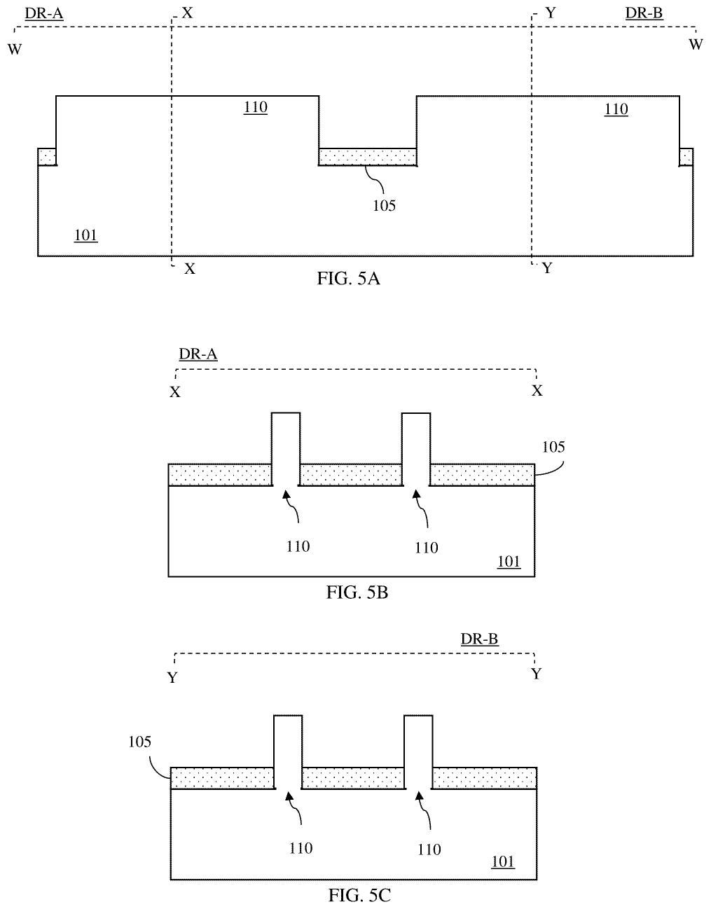

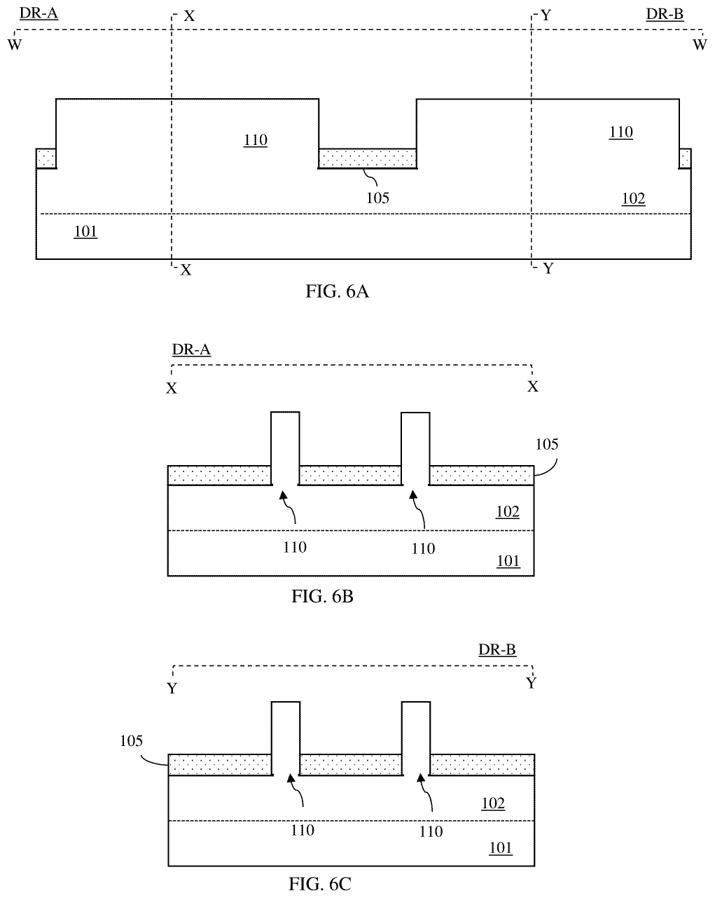

If the semiconductor fins 110 are patterned into the upper portion of a bulk semiconductor substrate, as illustrated, an insulator layer 105 (e.g., a silicon dioxide layer) can further be formed on the semiconductor substrate 101 over the semiconductor fins 110 and then recessed such that the insulator layer 105 laterally surrounds the lower portions of the semiconductor fins and extends laterally between adjacent semiconductor fins 110 (see FIGS. 5A-5C). Additionally, one or more dopant implantation processes can be performed in order to form doped well regions 102 to provide electrical isolation from the lower portion of the semiconductor substrate 101 (see FIGS. 6A-6C). Techniques for forming such doped well regions to provide electrical isolation between upper and lower portions of a bulk semiconductor substrate are well known in the art and, thus, the detailed have been omitted from this specification in order to allow the reader to focus on the salient aspects of the disclosed embodiments.

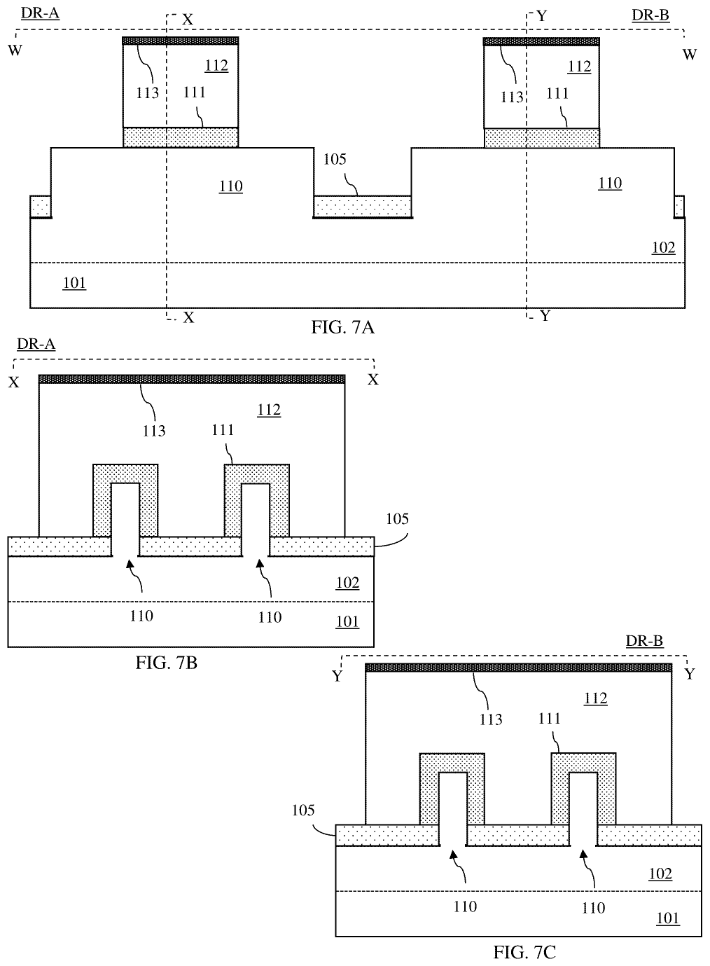

Sacrificial gate stack(s) for any FET(s) to be formed on the semiconductor substrate 101 can then be formed (see process 304 and FIGS. 7A-7C). For example, a first material layer can be formed on each semiconductor body. The first material layer 111 can, for example, be a relatively thick dielectric layer, such as a relatively thick oxide layer grown, for example, on exposed surfaces of the semiconductor fins 110. Alternatively, the first material layer 111 could be any other material suitable for use as a sacrificial material layer during RMG processing. A second material layer 112 can then be formed on the first material layer 111. The second material layer 112 can, for example, be a polysilicon layer, an amorphous silicon layer, a silicon nitride layer or a layer of any other material that is different from the first material layer and suitable for use as a sacrificial material layer during RMG processing. A hardmask layer (e.g., a silicon nitride hardmask layer 113) can be formed on the second material layer 112. This multi-layered structure can then be lithographically patterned and etched into one or more sacrificial gate stacks. Thus, the sacrificial gate stack(s) will have an approximately uniform length (e.g., the lengths of the first and second material layers in each stack will be approximately the same). The overall length of any sacrificial gate stack (including the lengths of the first and second material layers therein) can vary by design (e.g., depending upon the particular application). For example, in some embodiments, the length of a sacrificial gate stack following process 304 could be greater than 50 nm (e.g., at approximately 60 nm). In other embodiments, it could be less than 50 nm or even less than 25 nm. For purposes of illustration, FIGS. 7A-7C show two discrete sacrificial gate stacks: one on the semiconductor fins for the FINFET with the scaled effective gate length being formed in DR-A and one on the semiconductor fins for the FINFET without the scaled effective gate length being formed in DR-B.

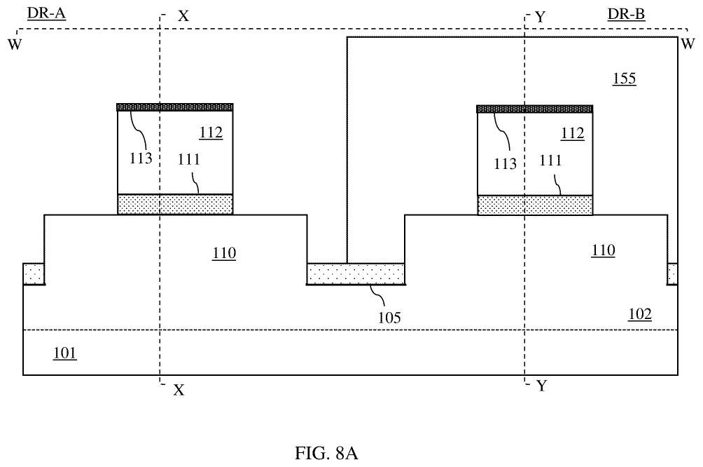

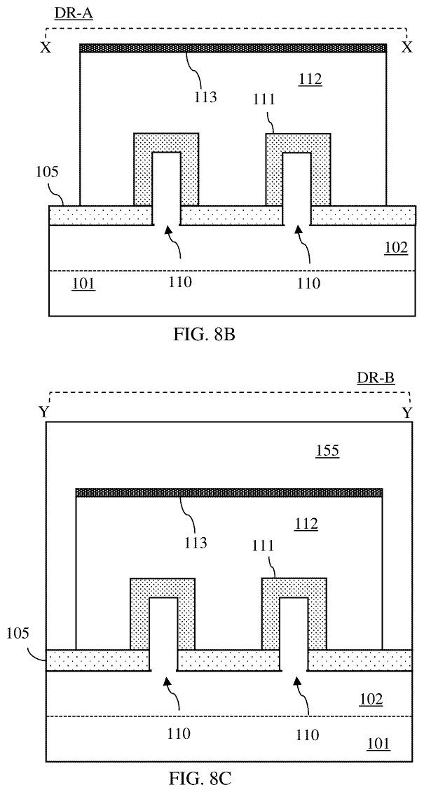

A mask 155 can then be formed over DR-B to protect the sacrificial gate structure therein (see process 306 and FIGS. 8A-8C). The mask 155 can, for example be a hardmask (e.g., a spin-on carbon (SOC) hardmask) formed and patterned so as to cover DR-B, while leaving DR-A exposed.

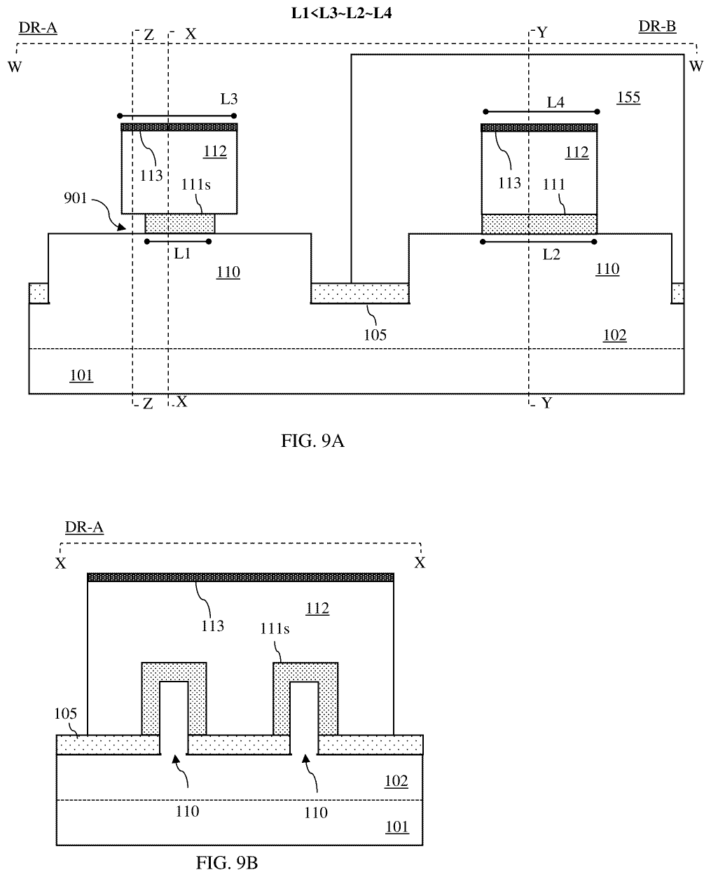

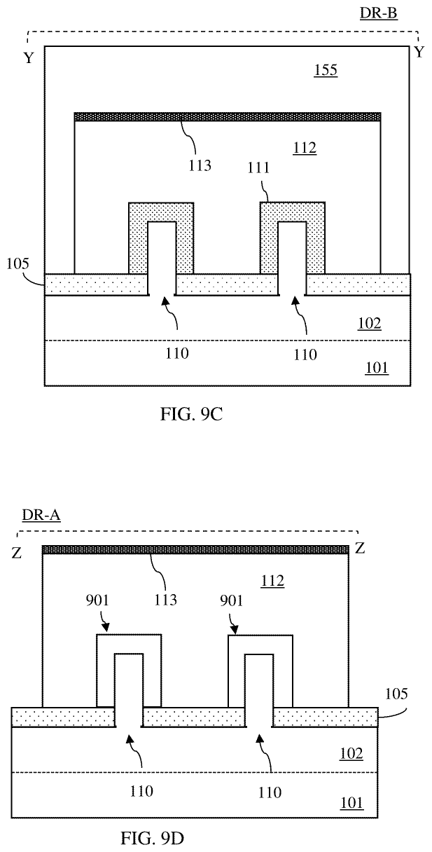

Exposed vertical surfaces of the first material layer 111 of the gate stack in DR-A can be selectively laterally etched to undercut the second material layer 112 (see process 308 and FIGS. 9A-9D). Laterally etching the exposed vertical surfaces of the first material layer 111 shortens this layer from opposing sides relative to the second material layer 112, thereby forming shortened first material layer 111 in the gate stack in DR-A. Furthermore, the lateral etch process creates cavities 901 on opposing sides of the gate stack between edge regions of the second material layer 112. This etch process can, for example, be an isotropic etch process that is selective to the material of the first material layer 111 over other exposed materials. For example, if the first material layer 111 is an oxide layer and the second material layer 112 is a polysilicon layer, the etch process could be a wet etch process, such as a hydrofluoric acid (HF) wet etch process, suitable for isotropically etching an oxide relative to polysilicon. In some embodiments, the etch process can be performed so as to etch 2-5 nm away from opposing sides of the first material layer 111. Thus, in some embodiments, following process 308, the difference between the length (L1) of the shortened section 111s of the first material layer 111 (which will corresponding the scaled effective gate length) and the length (L3) of the second material layer 112 could range from 4-10 nm or more. For example, in some embodiments, following process 308, the second material layer 112 could be 60 nm and the shortened section 11 is of the first material layer could range from 50-56 nm with each cavity being 2-5 nm deep.

It should be noted that, due to the protection of the mask 155 over DR-B during process 308, the length (L2) of the first material layer 111 and the length (L4) of the second material layer 112 of any sacrificial gate stack in DR-B will remain the same (i.e., L2˜L4). Furthermore, depending upon patterning at process 304, L2 and L4 can also be approximately equal to L3 discussed above.

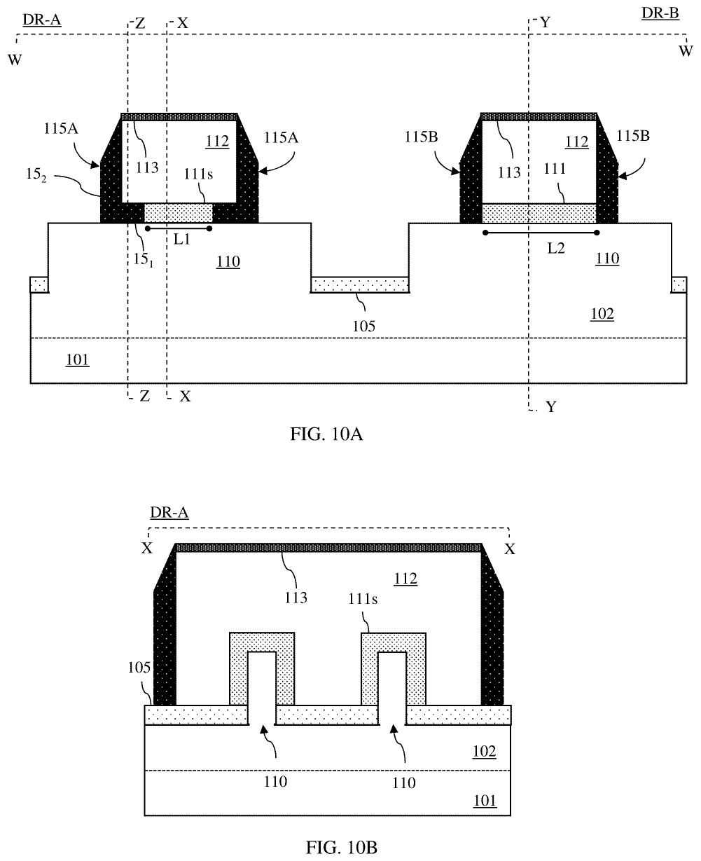

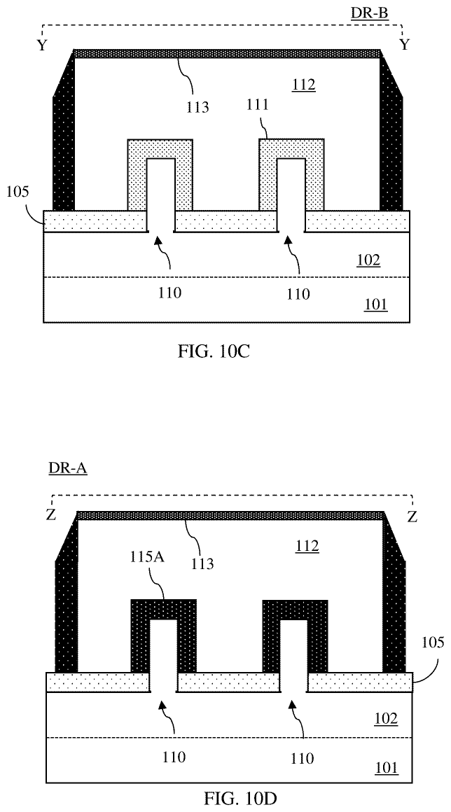

The mask 155 over DR-B can then be selectively removed and conventional FET processing (e.g., conventional FINFET processing) can be performed in order to complete the semiconductor structure 100.1 of FIGS. 1A-1D or 100.2 of FIGS. 2A-2D. Specifically, gate sidewall spacers can be formed on the gate stacks (see process 310 and FIGS. 10A-10D). For example, a sidewall spacer material layer can be conformally deposited over the partially completed structure. The sidewall spacer material layer can be a layer of, for example, silicon nitride, silicon carbon nitride, silicon boron carbon nitride or any other suitable sidewall spacer material layer. Due to the conformal nature of the deposition process, this sidewall spacer material layer can completely fill the cavities 901 on the opposing sides of the shortened section 111s of the first material layer 111 between the edge region of the second material layer 112 and the adjacent semiconductor fin 110. Alternatively, however, depending upon the size of the openings to the cavities (e.g., as a function of the thickness of the first material layer), this sidewall spacer material layer can pinch off at the openings to the cavities 901 prior to completely filling them such that air-gaps are contained therein (not shown). In any case, after the sidewall spacer material layer is deposited, an anisotropic etch process can be performed in order to remove exposed portions of the sidewall spacer material layer that are essentially horizontally oriented and leaving intact those exposed portions that are essentially vertically oriented. As a result, the gate sidewall spacers 115A on the gate stack in DR-A have the first and second sections 15₁-15₂ described in detail above with regard to the structure embodiments and the gate sidewall spacers 115B on the gate stack in DR-B are vertically oriented and flush with the vertically aligned surfaces of the first and second material layers therein.

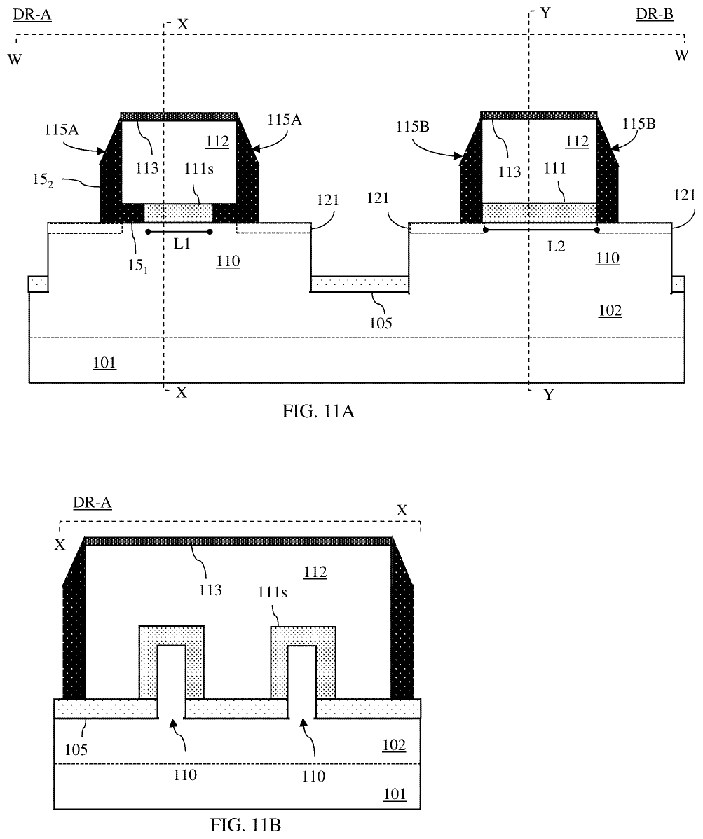

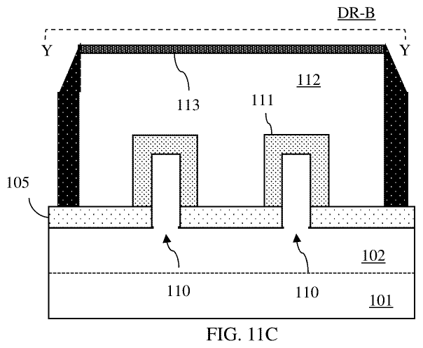

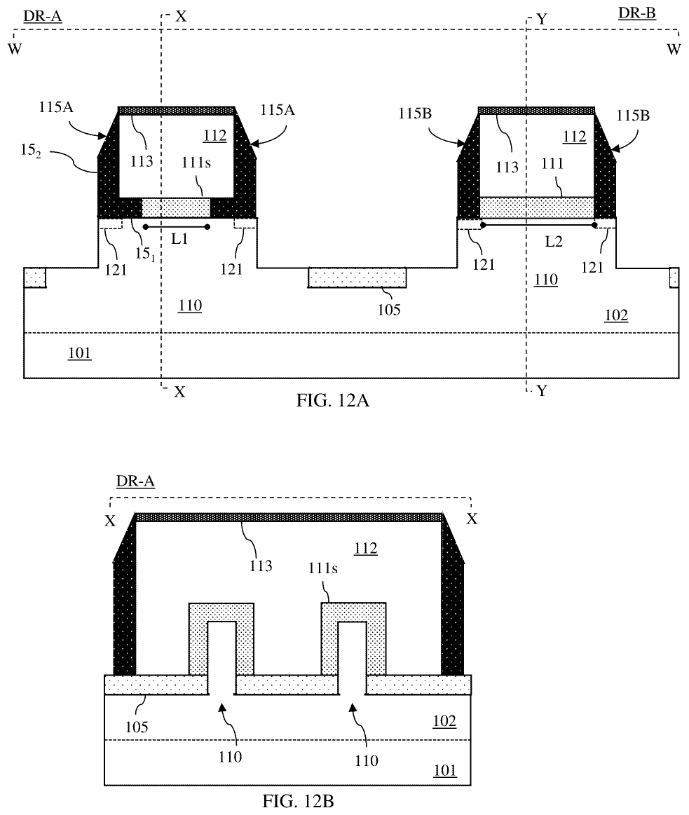

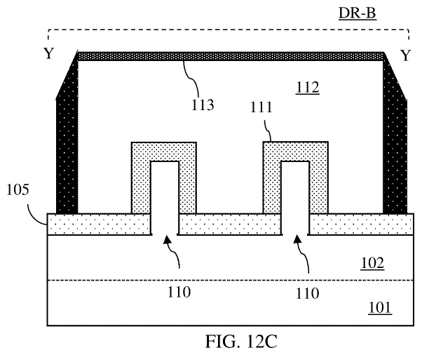

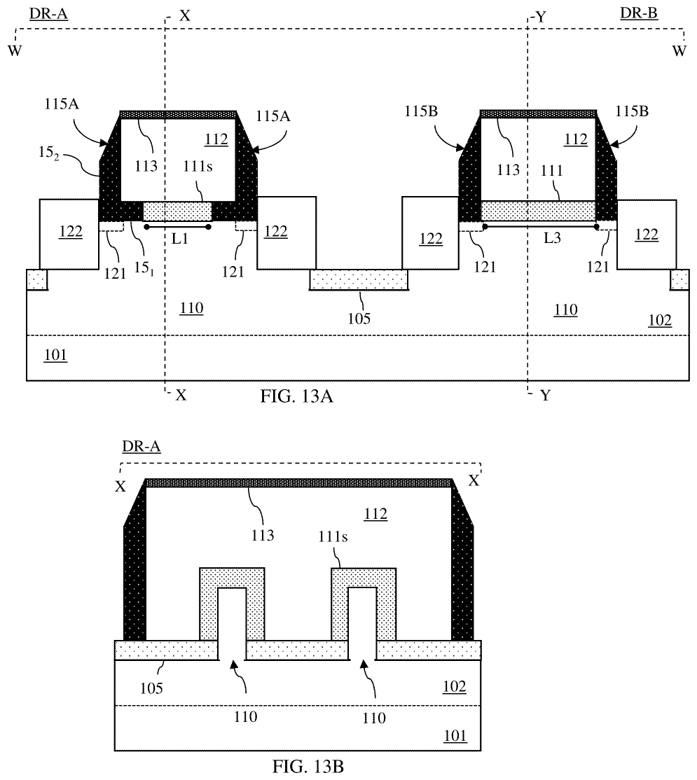

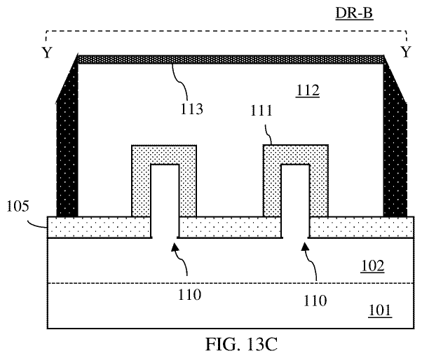

Following formation of the gate sidewall spacers, conventional source/drain processing can be performed (see process 312). Exemplary FINFET source/drain processing can include but is not limited to formation of source/drain extension regions 121 by dopant implantation (see FIGS. 11A-11C) and source/drain region 122 formation by formation of source/drain recesses (see FIGS. 12A-12C) and epitaxial growth of in situ doped semiconductor layers within the source/drain recesses (FIGS. 13A-13C). Those skilled in the art will recognize that, for FETs having the same type conductivity (e.g., all NFETs or all PFETs), these processes can be performed concurrently. However, if one FET is a PFET and the other is an NFET, source/drain processing of a PFET can be performed while the partially completed NFET is masked and vice versa.

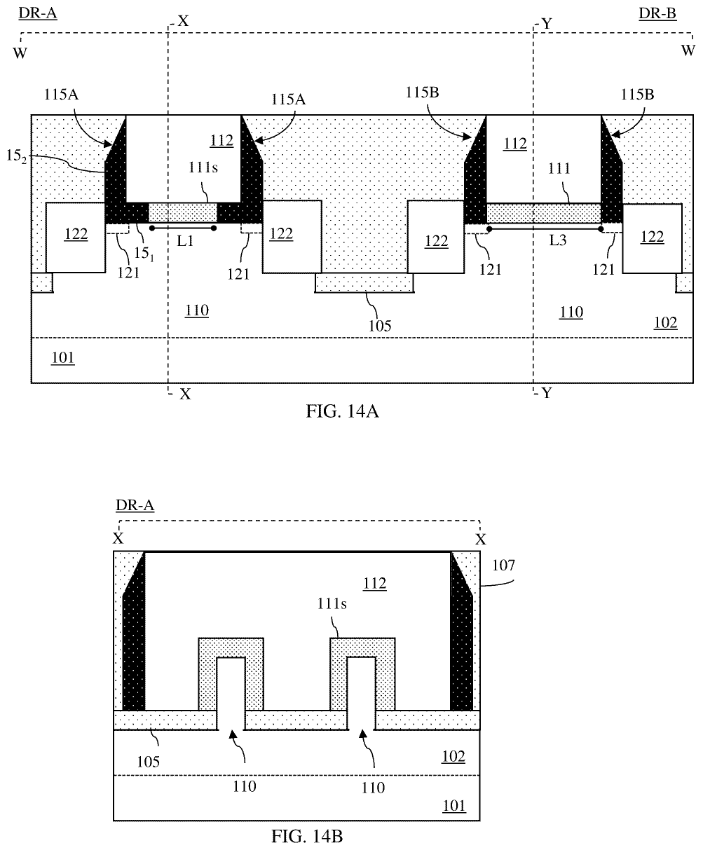

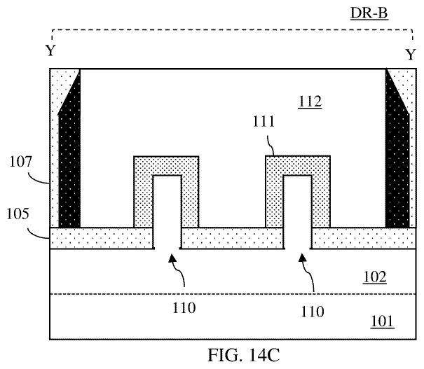

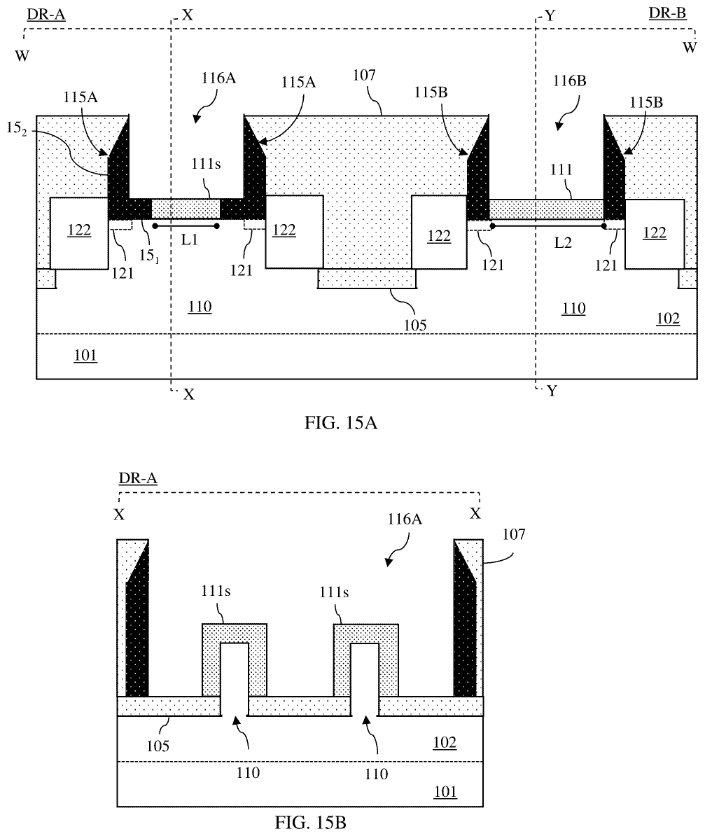

Following formation of source/drain regions 122, one or more additional dielectric layers 107 (e.g., including one or more layers of dielectric material, interlayer dielectric (ILD) material) can be deposited over the partially completed structure (see process 314 and FIGS. 14A-14C). The ILD material can include, for example, one or more layers of silicon dioxide, silicon nitride, a doped silicon glass (e.g., phosphosilicate glass (PSG) or borophosphosilicate glass (BPSG)), or any other suitable ILD material. A chemical mechanical polishing (CMP) process can be performed in order to expose the top surface of the second material layer 112 of each sacrificial gate stack (see FIGS. 14A-14C).

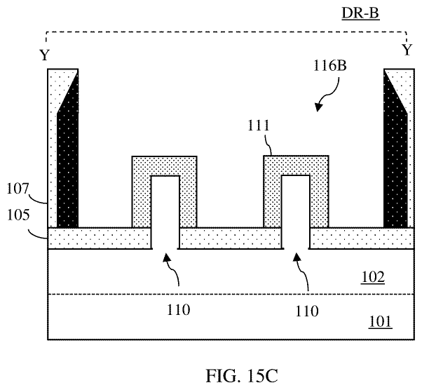

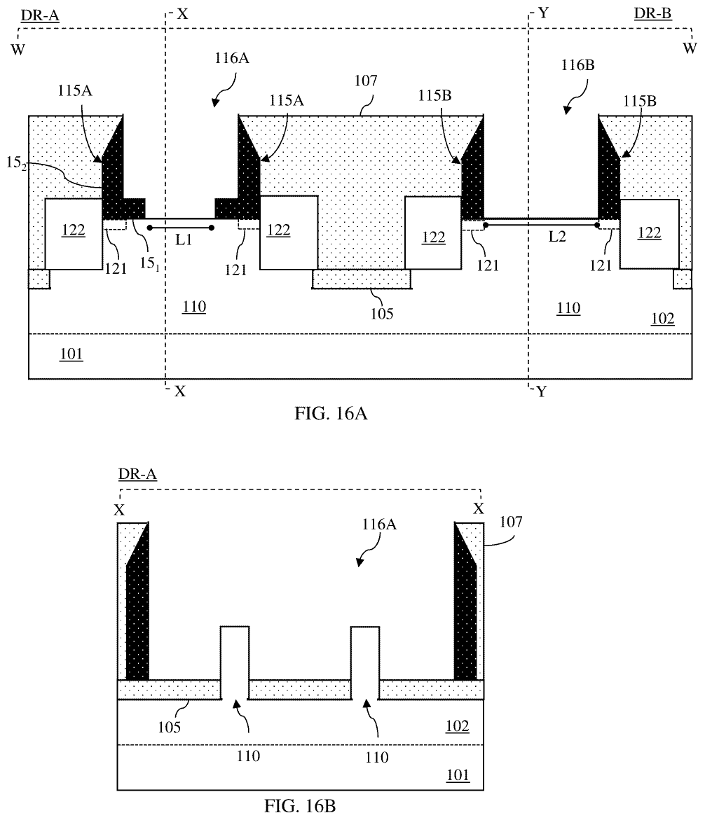

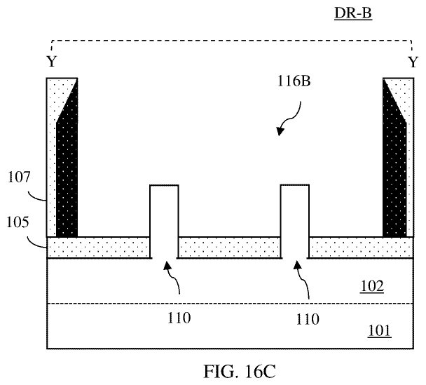

In order to form the semiconductor structure 100.1 of FIGS. 1A-1D, the second material layer 112 and then the first material layer 111 can be selectively removed from the sacrificial gate stack(s), thereby forming a gate opening 116A with a narrow bottom portion where the shortened section 111s of the first material layer was removed and, if applicable, a gate opening 116B without such a narrow bottom portion (see process 322 and FIGS. 15A-15C and 16A-16C). Techniques for selectively removing polysilicon and oxide layers of a sacrificial gate structure are well known in the art and, thus, the details thereof have been omitted from this specification in order to allow the reader to focus on the salient aspects of the disclosed embodiments. The gate opening(s) 116A, 116B can be lined with a gate dielectric layer 124, including one or more conformal layers of gate dielectric material (e.g., a relatively thin conformal high-K gate dielectric layer). Then, the remaining space within each gate opening can be filled with a gate conductor layer 125, including one or more layers of gate conductor material (e.g., a WF metal or metal alloy layer and, optionally, a conductive fill material layer), on the gate dielectric layer 124 (see process 324 and the semiconductor structure 100.1 of FIGS. 1A-1D). CMP can further be performed to remove any gate dielectric and gate conductor materials from above the top surface of the additional dielectric layer(s) 107. Thus, as discussed in detail above with regard to the semiconductor structure 100.1 and illustrated in FIGS. 1A-1D, following processes 322-324, in the resulting gate structure 126.1A specifically, the gate dielectric layer 124 will be within both the first and second portions 26₁-26₂ and the gate conductor layer 125 may be within the first portion 26₁ depending on the thickness of the gate dielectric layer 124 relative to the first section 15₁ and in any case will be within the second portion 26₂. Additionally, surfaces of the adjacent semiconductor fin, the first section 15₁ of the gate sidewall spacer 115A, and the second section 15₂ of the gate sidewall spacer 115A will be immediately adjacent to the gate dielectric layer 124 and separated from the gate conductor layer 125 by the gate dielectric layer 124.

Alternatively, in order to form the semiconductor structure 100.2 of FIGS. 2A-2D, the second material layer 112 only (and, specifically, not the first material layer) can be selectively removed from the sacrificial gate stack(s), thereby forming a gate opening 116A above the shortened section 111 is of the first material layer and, if applicable, a gate opening 116B above a non-shorted section of the first material layer 111 (see process 332 and FIGS. 15A-15C). Techniques for selectively removing a polysilicon layer of a sacrificial gate structure are well known in the art and, thus, the details thereof have been omitted from this specification in order to allow the reader to focus on the salient aspects of the disclosed embodiments. In this case, material of the first material layer should specifically be a material suitable for use as an additional gate dielectric layer (e.g., an oxide layer). In any case, the gate opening(s) 116A, 116B can be lined with a gate dielectric layer 124, including one or more conformal layers of gate dielectric material (e.g., a relatively thin conformal high-K gate dielectric layer). Then, the remaining space in each gate opening can be filled with a gate conductor layer 125, including one or more layers of gate conductor material (e.g., a WF metal or metal alloy layer and, optionally, a conductive fill material layer) (see process 334 and the semiconductor structure 100.2 of FIGS. 2A-2D). CMP can further be performed to remove any gate dielectric and gate conductor materials from above the top surface of the additional dielectric layer(s) 107. Thus, as discussed in detail above with regard to the semiconductor structure 100.2 and illustrated in FIGS. 2A-2D, in the resulting gate structure 126.2A specifically, the first portion 26₁ will be the remaining shortened section 111 is of the first material layer, which will function effectively as an additional gate dielectric layer, and the second portion 26₂ will include the gate dielectric layer 124 that lines the gate opening and the gate conductor layer 125 that fills the remaining space in the gate opening. Additionally, surfaces of the additional gate dielectric layer, the first section 15₁ of the gate sidewall spacer 115A, and the second section 15₂ of the gate sidewall spacer 115A are immediately adjacent to the gate dielectric layer 124 and separated from the gate conductor layer 125 by the gate dielectric layer 124.

Additional processing can further be performed in order to complete the semiconductor structure (see process 342). This additional processing can include, but is not limited to, middle of the line (MOL) process to form contacts (not shown) to the source/drain regions and the gate structure of each FET as well as back end of the line (BEOL) processing. Such processing is well known in the art and, thus, the details thereof have been omitted from the specification in order to allow the reader to focus on the salient aspects of the disclosed embodiments.

In the structures and method described above, a semiconductor material refers to a material whose conducting properties can be altered by doping with an impurity. Semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region. Furthermore, when a semiconductor region or layer is described as being at a higher conductivity level than another semiconductor region or layer, it is more conductive (less resistive) than the other semiconductor region or layer; whereas, when a semiconductor region or layer is described as being at a lower conductivity level than another semiconductor region or layer, it is less conductive (more resistive) than that other semiconductor region or layer.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the terminology used herein is for the purpose of describing the disclosed structures and methods and is not intended to be limiting. For example, as used herein, the singular forms “a”, “an” and “the” are intended to include the plural forms as well, unless the context clearly indicates otherwise. Additionally, as used herein, the terms “comprises”, “comprising”, “includes”, and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right”, “left”, “vertical”, “horizontal”, “top”, “bottom”, “upper”, “lower”, “under”, “below”, “underlying”, “over”, “overlying”, “parallel”, “perpendicular”, etc., are intended to describe relative locations as they are oriented and illustrated in the drawings (unless otherwise indicated) and terms such as “touching”, “in direct contact”, “abutting”, “directly adjacent to”, “immediately adjacent to”, etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor body;
a gate structure including: a first portion on the semiconductor body and a second portion on the first portion, wherein the second portion includes: a gate dielectric layer; and a gate conductor layer and further has an edge region that extends laterally beyond the first portion, and wherein the first portion includes an additional gate dielectric layer between the semiconductor body and the gate dielectric layer; and
gate sidewall spacers adjacent to opposing sides of the gate structure, wherein each gate sidewall spacer has a first section and a second section, wherein the first section is positioned laterally adjacent to the first portion of the gate structure between the edge region of the second portion of the gate structure and the semiconductor body, and wherein the second section is positioned laterally adjacent to the first section and to the second portion of the gate structure.

2. The structure of claim 1, wherein the gate dielectric layer and the additional gate dielectric layer include different gate dielectric materials.

3. The structure of claim 1, wherein the gate dielectric layer includes at least a high-K dielectric layer, wherein the additional gate dielectric layer includes an oxide layer, and wherein the gate conductor layer includes at least a layer of any of a metal and a metal alloy.

4. The structure of claim 1, wherein the second portion is within a gate opening between the second section of each gate sidewall spacer and includes the gate dielectric layer lining the gate opening and the gate conductor layer on the gate dielectric layer, and wherein surfaces of the additional gate dielectric layer, the first section of each gate sidewall spacer and the second section of each gate sidewall spacer are immediately adjacent to the gate dielectric layer and separated from the gate conductor layer by the gate dielectric layer.

5. The structure of claim 1, wherein the additional gate dielectric layer has a same thickness as the first section of each gate sidewall spacer.

6. The structure of claim 1, wherein the additional gate dielectric layer is thicker than the gate dielectric layer.

7. The structure of claim 1, wherein the semiconductor body includes a semiconductor fin, and wherein the gate structure and each gate sidewall spacer are on a top surface and adjacent opposing sides of the semiconductor fin.

8. The structure of claim 1, wherein the gate structure includes a replacement metal gate.

9. A structure comprising:
a substrate;
a field effect transistor on the substrate and including:
a semiconductor fin;
a gate structure including: a first portion on a top surface and opposing sides of the semiconductor fin; and a second portion on the first portion, wherein the second portion includes: a gate dielectric layer; and a gate conductor layer on the gate dielectric layer and further has an edge region that extends laterally beyond the first portion, and wherein the first portion includes an additional gate dielectric layer between the semiconductor fin and the gate dielectric layer; and
gate sidewall spacers adjacent to opposing sides of the gate structure, wherein each gate sidewall spacer has a first section and a second section, wherein the first section is positioned laterally adjacent to the first portion of the gate structure between the edge region of the second portion of the gate structure and the semiconductor fin, and wherein the second section is positioned laterally adjacent to the first section and to the second portion of the gate structure; and
an additional field effect transistor on the substrate, wherein the additional field effect transistor includes an additional gate structure with a longer effective gate length than the gate structure.

10. The structure of claim 9, wherein the gate dielectric layer and the additional gate dielectric layer include different gate dielectric materials.

11. The structure of claim 9, wherein the gate dielectric layer includes at least a high-K dielectric layer, wherein the additional gate dielectric layer includes an oxide layer, and wherein the gate conductor layer includes at least a layer of any of a metal and a metal alloy.

12. The structure of claim 9, wherein the second portion is within a gate opening between the second section of each gate sidewalls spacer and includes the gate dielectric layer lining the gate opening and the gate conductor layer on the gate dielectric layer, and wherein surfaces of the additional gate dielectric layer, the first section of each gate sidewall spacer and the second section of each gate sidewall spacer are immediately adjacent to the gate dielectric layer and separated from the gate conductor layer by the gate dielectric layer.

13. The structure of claim 9, wherein the additional gate dielectric layer has a same thickness as the first section of each gate sidewall spacer and is thicker than the gate dielectric layer.

14. The structure of claim 9, wherein the additional field effect transistor further includes an additional semiconductor fin and wherein the additional gate structure has approximately equal lengths proximal to the additional semiconductor fin and distal to the additional semiconductor fin.

15. The structure of claim 9, wherein the gate structure and the additional gate structure include replacement metal gates.

16. A method comprising:
providing a substrate; and
forming, on the substrate, a structure including:
a semiconductor body;
a gate structure including: a first portion on the semiconductor body and a second portion on the first portion, wherein the second portion includes: a gate dielectric layer; and a gate conductor layer and further has an edge region that extends laterally beyond the first portion, and wherein the first portion includes an additional gate dielectric layer between the semiconductor body and the gate dielectric layer; and
gate sidewall spacers adjacent to opposing sides of the gate structure, wherein each gate sidewall spacer has a first section and a second section, wherein the first section is positioned laterally adjacent to the first portion of the gate structure between the edge region of the second portion of the gate structure and the semiconductor body, and wherein the second section is positioned laterally adjacent to the first section and to the second portion of the gate structure.

17. The method of claim 16, wherein the forming of the structure includes:
forming the semiconductor body on the substrate;
forming a gate stack on the semiconductor body, wherein the gate stack includes: a first material layer immediately adjacent to the semiconductor body and a second material layer on the first material layer, wherein the second material layer is different from the first material layer;
etching exposed surfaces of the first material layer of the gate stack to form a cavity; and
forming the gate sidewall spacers such that each gate sidewall spacer has the first section in the cavity and the second section positioned laterally adjacent to the first section and the second material layer of the gate stack.

18. The method of claim 17,
wherein the first material layer includes an additional gate dielectric layer,
wherein the forming of the structure further includes forming the gate structure,
wherein the forming of the gate structure includes:
removing the second material layer to form a gate opening;
lining the gate opening with the gate dielectric layer; and
forming the gate conductor layer on the gate dielectric layer within the gate opening,
wherein the first portion of the gate structure includes the additional gate dielectric layer and has a same thickness as the first section of each gate sidewall spacer,
wherein the second portion of the gate structure includes: the gate dielectric layer lining the gate opening and the gate conductor layer in the gate opening on the gate dielectric layer, and
wherein surfaces of the additional gate dielectric layer, the first section of each gate sidewall spacer, and the second section of each gate sidewall spacer are immediately adjacent to the gate dielectric layer and separated from the gate conductor layer by the gate dielectric layer.

19. The method of claim 17, wherein the forming of the semiconductor body includes forming a semiconductor fin and wherein the forming of the gate stack includes forming the gate stack adjacent to a top surface and opposing sides of the semiconductor fin.

20. The method of claim 16, wherein the forming of the structure includes: forming a transistor including the semiconductor body, the gate structure, and the gate sidewalls spacer; and concurrently forming an additional transistor with a longer effective gate length than the transistor.
